(19) United States
(12) Patent Application Publication
(10) Pub. No.: US 2021/0108138 A1
(43) Pub. Date: Apr. 15, 2021

(54) MATERIALS COMPRISING MATRIX MATERIAL DOPED WITH METAL AND METHODS FOR FABRICATION

(71) Applicant: Beneq Oy, Espoo (FI)

(72) Inventors: Saoussen Merdes, Espoo (FI); Pekka J. Soininen, Espoo (FI); Erik Østreng, Espoo (FI)

(73) Assignee: Beneq Oy, Espoo (FI)

(21) Appl. No.: 16/601,849

(22) Filed: Oct. 15, 2019

(51) Int. Cl. C09K 11/77; C09K 11/02

(52) U.S. Cl. CPC C09K 11/7771; C09K 11/025

(57) ABSTRACT

A material comprising a first layer of matrix material doped with a dopant metal is disclosed. The matrix material comprises a rare-earth metal, oxygen, and one or both of sulfur and selenium. In the first layer of matrix material doped with the dopant metal, the rare-earth metal has an oxidation state of +3 and the dopant metal has an oxidation state of +2. Further is disclosed a method for fabricating the material and a device comprising the material.

### TECHNICAL FIELD

The present disclosure relates to a material comprising a first layer of matrix material doped with a dopant metal. The present disclosure further relates to a method for fabricating a material comprising a first layer of matrix material doped with a dopant metal. The present disclosure further relates to a device comprising the material.

### BACKGROUND

The emission of various colors can be generated by doping a semiconductor matrix material with different lanthanide ions, that may act as luminescent centers. Yttrium oxysulfide doped with europium (Y₂O₂S:Eu) is a phosphor material that can be produced or grown by several techniques such as pulse laser deposition, hydrothermal method, sol-gel template method, decomposition method, etc. However, when using these growth techniques, the europium dopant oxidizes in its trivalent form Eu³⁺. This results in red being the color emission generated by the Y₂O₂S:Eu material. The inventors have recognized a need for a material being able to emit other colors, such as blue, for use in e.g. displays.

### SUMMARY

A material is disclosed. The material may comprise a first layer of matrix material doped with a dopant metal. The matrix material may comprise a rare-earth metal, oxygen, and one or both of sulfur and selenium. In the first layer of matrix material doped with the dopant metal, the rare-earth metal has an oxidation state of +3 and the dopant metal may have an oxidation state of +2.

A method for fabricating a material on the surface of a substrate is disclosed. The method may comprise forming a first layer of matrix material doped with a dopant metal, wherein the matrix material comprises a rare-earth metal, oxygen, and one or both of sulfur and selenium. The first layer of matrix material doped with the dopant metal may be formed in a reaction space through alternately repeated surface reactions of precursors by

a) depositing a first deposit of matrix material by exposing a deposition surface to a precursor for rare-earth metal, a precursor for oxygen, and one or both of a precursor for sulfur and a precursor for selenium in any order, and

b) doping the surface of the first deposit of matrix material with a dopant metal by exposing the deposition surface to a precursor for dopant metal,

with the proviso that exposing the deposition surface to a precursor for dopant metal is preceded with exposing the deposition surface to either a precursor for sulfur or a precursor for selenium configured to provide the dopant metal, in the first layer of matrix material doped with the dopant metal, with an oxidation state of +2, while the rare-earth metal has an oxidation state of +3.

A device comprising a material as disclosed in the current application is disclosed.

### BRIEF DESCRIPTION OF THE DRAWINGS

The accompanying drawings, which are included to provide a further understanding of the embodiments and constitute a part of this specification, illustrate various embodiments. In the drawings:

FIG. 1 presents a flow-chart illustration of a method according to one embodiment;

FIG. 2 presents a schematic illustration of a material on a substrate according to one embodiment;

FIGS. 3A and 3B present the photoluminescence spectra from Y₂O₃₋ₓSₓ:Eu prepared using either (a) the Eu(thd)₃/O₃ (process P1) or (b) the Eu(thd)₃/H₂S (process P2) pulse sequence;

FIG. 4 presents the measured XPS spectra for S 2s core levels in films grown using Eu(thd)₃/O₃ (process P1) and Eu(thd)₃/H₂S (process P2) pulse sequences;

FIGS. 5A and 5B present the measured and fitted XPS spectra for (a) Y 3d core levels in films grown using Eu(thd)₃/O₃ (process P1) and (b) Y 3d/S2 p core levels in films grown using Eu(thd)₃/H₂S (process P2) pulse sequences; and

FIG. 6 presents the XRD spectra measured for the films grown using Eu(thd)₃/O₃ (process P1) and Eu(thd)₃/H₂S (process P2) pulse sequences.

### DETAILED DESCRIPTION

A material is disclosed. The material may comprise a first layer of matrix material doped with a dopant metal. The matrix material may comprise a rare-earth metal, oxygen, and one or both of sulfur and selenium. In the first layer of matrix material doped with the dopant metal, the rare-earth metal has an oxidation state of +3 and the dopant metal has an oxidation state of +2.

A method for fabricating a material on the surface of a substrate is disclosed. The method may comprise forming a first layer of matrix material doped with a dopant metal, wherein the matrix material comprises a rare-earth metal, oxygen, and one or both of sulfur and selenium. The first layer of matrix material doped with the dopant metal may be formed in a reaction space through alternately repeated surface reactions of precursors by

a) depositing a first deposit of matrix material by exposing a deposition surface to a precursor for rare-earth metal, a precursor for oxygen, and one or both of a precursor for sulfur and a precursor for selenium in any order, and

b) doping the surface of the first deposit of matrix material with a dopant metal by exposing the deposition surface to a precursor for dopant metal,

with the proviso that exposing the deposition surface to a precursor for dopant metal is preceded with exposing the deposition surface to either a precursor for sulfur or a precursor for selenium configured to provide the dopant metal, in the first layer of matrix material doped with the dopant metal, with an oxidation state of +2, while the rare-earth metal has an oxidation state of +3.

In one embodiment, b) of exposing the deposition surface to the precursor for dopant metal is followed by exposing the deposition surface to either a precursor for sulfur or a precursor for selenium. In one embodiment, b) of exposing the deposition surface to the precursor for dopant metal is followed by exposing the deposition surface to either a precursor for sulfur or a precursor for selenium configured to provide the dopant metal, in the first layer of matrix material doped with the dopant metal, with an oxidation state of +2, while the rare-earth metal has an oxidation state of +3.

In this specification, unless otherwise stated, the term “the precursor for sulfur or precursor for selenium configured to provide the dopant metal with an oxidation state of +2” or similar terms, are used to address a precursor having the ability to reduce the oxidation state of the dopant metal. I.e. a reducing gas or a reducing vapor may be used as such a precursor.

The inventors surprisingly found out that when using as a precursor for sulfur and/or a precursor for selenium as a precursor gas, wherein the oxidation state of the sulfur or selenium, respectively, is low, e.g. −2, enables the production of a material, wherein the oxidation state of the dopant metal is reduced to +2 instead of +3. I.e. in the first layer of matrix material doped with the dopant metal, the rare-earth metal may have an oxidation state of +3 and the dopant metal may have an oxidation state of +2.

In one embodiment, the material is a phosphor material. A phosphor material is a material that may exhibit the phenomenon of luminescence, i.e. it emits light when being excited with electromagnetic radiation, an electron beam, and/or an electric current/field.

In one embodiment, the first layer of matrix material may emit electromagnetic radiation with a wavelength of 400-500 nm or 450-485 nm when being excited. Electromagnetic radiation within such wavelength ranges may generally be considered as blue light.

In this specification, unless otherwise stated, the term “the surface”, “surface of the substrate”, “deposition surface”, or “surface of the first/second deposit” is used to address the surface of the substrate or the surface of the already formed layer or deposit on the substrate. Therefore, the terms “surface”, “surface of the substrate”, “deposition surface”, and “surface of the first/second deposit” include the surface of the substrate which has not yet been exposed to any precursors and the surface which has been exposed to one or more precursors. The “deposition surface” thus changes during the deposition process, when chemicals get chemisorbed onto the surface.

A device comprising a material as disclosed in the current application is disclosed. In one embodiment, the device is a light-emitting device.

The phosphor material as disclosed in the current application may be used in a light-emitting device, including a light-emitting diode.

The inventors surprisingly found out that it is possible to fabricate a material comprising a first layer of matrix material doped with a dopant metal, wherein the matrix material comprises a rare-earth metal, oxygen, and one or both of sulfur and selenium, such that, in the first layer of matrix material doped with the dopant metal, the rare-earth metal has an oxidation state of +3 and the dopant metal has an oxidation state of +2. Such a material has the added utility of having properties to be used as a phosphor material able to emit blue light when excited.

The inventors surprisingly found out that by using atomic layer deposition (ALD) it is possible to control the oxidation state of the dopant metal, e.g. europium, in the matrix material, e.g. Y₂O₃₋ₓSₓ, through the doping configuration. Thus, during the deposition or growth process, Eu on the surface can be deliberately exposed to reducing H₂S gas in order to generate a divalent oxidation state of Eu. Being able to control the oxidation state of the dopant metal resulted in the surprising possibility of being able to fabricate a phosphor material that emits blue color instead of red. The material may further comprise a second layer of matrix material doped with a dopant metal, wherein the matrix material comprises a rare-earth metal, oxygen, and one or both of sulfur and selenium, wherein, in the second layer of matrix material doped with the dopant metal, the rare-earth metal has an oxidation state of +3 and the dopant metal has an oxidation state of +3. When doping a matrix material such as Y₂O₃₋ₓSₓ, with a dopant metal, such as Eu, the oxidation state of the dopant metal tends to assume its trivalent state. Such a doped matrix material will result in red light being emitted when being excited. I.e. the second layer of matrix material may emit electromagnetic radiation with a wavelength of 550-780 nm, or 600-750 nm, or 625-740 nm when being excited.

In one embodiment, the method further comprises forming a second layer of matrix material doped with a dopant metal, wherein the matrix material comprises a rare-earth metal, oxygen, and one or both of sulfur and selenium, wherein the second layer of matrix material doped with the dopant metal is formed in a reaction space through alternately repeated surface reactions of precursors by

c) depositing a second deposit of matrix material by exposing a deposition surface to a precursor for rare-earth metal, a precursor for oxygen, and one or both of a precursor for sulfur and a precursor for selenium in any order, and

d) doping the surface of the second deposit of matrix material with a dopant metal by exposing the deposition surface to a precursor for dopant metal,

wherein d) of exposing the deposition surface to a precursor for dopant metal is followed by exposing the deposition surface to a precursor for oxygen, such that, in the second layer of matrix material doped with a dopant metal, the rare-earth metal has an oxidation state of +3 and the dopant metal has an oxidation state of +3.

In one embodiment, d) comprises the proviso that exposing the deposition surface to a precursor for dopant metal is preceded with exposing the deposition surface to a precursor for oxygen.

The inventors surprisingly found out that by controlling the conditions for d) of doping the deposit of matrix material, one is able to change the oxidation state of the dopant metal and thus to provide a phosphor material with properties useful for specific applications.

In one embodiment, exposing the deposition surface to a precursor for dopant metal is followed by exposing the deposition surface to a precursor for sulfur or a precursor for selenium. In one embodiment, exposing the deposition surface to a precursor for dopant metal is followed by exposing the deposition surface to a precursor for oxygen. In one embodiment, when doping the surface of the first deposit of matrix material with a dopant metal, exposing the deposition surface to a precursor for dopant metal is followed by exposing the deposition surface to a precursor for sulfur or a precursor for selenium. In one embodiment, when doping the surface of the second deposit of matrix material with a dopant metal, exposing the deposition surface to a precursor for dopant metal is followed by exposing the deposition surface to a precursor for oxygen.

The material comprising the first layer of matrix material doped with a dopant metal and the second layer of matrix material doped with a dopant metal may emit electromagnetic radiation with a wavelength of 400 to 750 nm when being excited. This radiation may be perceived as white light. I.e. as a result of comprising both the first layer and the second layer, which separately emit electromagnetic radiation with different wavelengths when being excited, the material has the added utility of emitting white light when being excited.

In one embodiment, depositing a first/second deposit of matrix material and doping the surface of the first/second deposit of matrix material are carried out by an ALD-type process. When the first/second deposit and the doping of the surface of the first/second deposit are fabricated on the surface of the substrate by an ALD-type process excellent conformality and uniformity is achieved for the formed layer(s).

The ALD-type process is a method for depositing uniform and conformal deposits or layers over substrates of various shapes, even over complex three dimensional structures. In the ALD-type process, the substrate is alternately exposed to at least two different precursors (chemicals), usually one precursor at a time, to form on the substrate a deposit or a layer by alternately repeating essentially self-limiting surface reactions between the surface of the substrate (on the later stages, naturally, the surface of the already formed layer or deposit on the substrate) and the precursors. As a result, the deposited material is “grown” on the substrate molecule layer by molecule layer.

The distinctive feature of the ALD-type process is that the surface to be deposited is exposed to two or more different precursors in an alternate manner with usually a purging period in between the precursor pulses. During a purging period the deposition surface is exposed to a flow of gas which does not react with the precursors used in the process. This gas, often called the carrier gas or the purge gas, is therefore inert towards the precursors used in the process and removes e.g. surplus precursor and by-products resulting from the chemisorption reactions of the previous precursor pulse. This purging can be arranged by different means. The basic requirement of the ALD-type process is that the deposition surface is purged between the introduction of a precursor for a metal and a precursor for a non-metal. The purging period ensures that the gas phase growth is limited and only surfaces exposed to the precursor gas participate in the growth. However, the purging step with an inert gas can, according to one embodiment, be omitted in the ALD-type process when applying two process gases, i.e. different precursors, which do not react with each other. Without limiting the present invention to any specific ALD-cycle, it can be mentioned, as an example only, that the purging period can be omitted between two precursors, which do not react with each other. I.e. the purging period can be omitted, in some embodiments of the present invention, e.g. between two different precursors for oxygen if they do not react with each other.

The alternate or sequential exposure of the deposition surface to different precursors can be carried out in different manners. In a batch type process at least one substrate is placed in a reaction space, into which precursor and purge gases are being introduced in a predetermined cycle. Spatial atomic layer deposition is an ALD-type process based on the spatial separation of precursor gases or vapors. The different precursor gases or vapors can be confined in specific process areas or zones while the substrate passes by. In the continuous ALD-type process constant gas flow zones separated in space and a moving substrate are used in order to obtain the time sequential exposure. By moving the substrate through stationary zones, providing precursor exposure and purging areas, in the reaction space, a continuous coating process is achieved enabling roll-to-roll coating of a substrate. In continuous ALD-type process the cycle time depends on the speed of movement of the substrate between the gas flow zones.

Other names besides atomic layer deposition (ALD) have also been employed for these types of processes, where the alternate introduction of or exposure to two or more different precursors lead to the growth of the layer, often through essentially self-limiting surface reactions. These other names or process variants include atomic layer epitaxy (ALE), atomic layer chemical vapour deposition (ALCVD), and corresponding plasma enhanced, photo-assisted and electron enhanced variants. Unless otherwise stated, also these processes will be collectively addressed as ALD-type processes in this specification.

The matrix material comprises a rare-earth metal, oxygen, and one or both of sulfur and selenium. In one embodiment, the matrix material consists of a rare-earth metal, oxygen, and one or both of sulfur and selenium. In one embodiment, the matrix material is formed of a rare-earth metal, oxygen and one or both of sulfur and selenium.

In one embodiment, the matrix material comprises a rare-earth metal, oxygen, and sulfur. In one embodiment, the matrix material consists of a rare-earth metal, oxygen, and sulfur. In on embodiment, the matrix material is formed of a rare-earth metal, oxygen and sulfur. In one embodiment, the matrix material comprises a rare-earth metal, oxygen, and selenium. In one embodiment, the matrix material consists of a rare-earth metal, oxygen, and selenium. In one embodiment, the matrix material is formed of a rare-earth metal, oxygen and selenium. In one embodiment, the matrix material comprises a rare-earth metal, oxygen, and both sulfur and selenium. In one embodiment, the matrix material consists of a rare-earth metal, oxygen, and both sulfur and selenium. In one embodiment, the matrix material is formed of a rare-earth metal, oxygen and both sulfur and selenium.

According to the International Union of Pure and Applied Chemistry (IUPAC) the lanthanides as well as yttrium and scandium are considered rare-earth metals.

In one embodiment, the rare-earth metal is yttrium, scandium, lanthanum, gadolinium, or lutetium.

In one embodiment, the dopant metal is europium.

Different precursors to be used in the method described in the current specification are generally available. In one embodiment, the precursor for rare-earth metal is selected from a group consisting of a precursor for yttrium, precursor for scandium, precursor for lanthanum, precursor for gadolinium, and precursor for lutetium. The precursor for yttrium may be selected from a group consisting of cyclopentadienyl compounds of yttrium, cyclooctadienyl compounds of yttrium, amidinato compounds of yttrium, and silyl-amide compounds of yttrium. The precursor for scandium may be selected from a group consisting of cyclopentadienyl compounds of scandium, cyclooctadienyl compounds of scandium, amidinato compounds of scandium, and silyl-amide compounds of scandium. The precursor for lanthanum may be selected from a group consisting of cyclopentadienyl compounds of lanthanum, cyclooctadienyl compounds of lanthanum, amidinato compounds of lanthanum, and silyl-amide compounds of lanthanum. The precursor for gadolinium may be selected from a group consisting of cyclopentadienyl compounds of gadolinium, cyclooctadienyl compounds of gadolinium, amidinato compounds of gadolinium, and silyl-amide compounds of gadolinium. The precursor for lutetium may be selected from a group consisting of cyclopentadienyl compounds of lutetium, cyclooctadienyl compounds of lutetium, amidinato compounds of lutetium, and silyl-amide compounds of lutetium.

In one embodiment the precursor for dopant metal is a precursor for europium. The precursor for europium may be selected from a group consisting of β-diketonate compounds of europium, fluorinated β-diketonate compounds of europium, cyclopentadienyl compounds of europium, cyclooctadienyl compounds of europium, amidinato compounds of europium, and silyl-amide compounds of europium.

In one embodiment, the precursor for oxygen is selected from a group consisting of water, hydrogen peroxide, carboxylic acid, methanol, ethanol, propanol, isopropanol, butanol, 2-butanol, tert-butanol, oxygen, ozone, nitrogen dioxide; and any combination or mixture thereof. In one embodiment, the precursor for oxygen is water or ozone. In one embodiment, the precursor for sulfur is elemental sulfur, H₂S, alkanethiol such as CH₃CH₂SH, dialkyldisulfide such as CH₃CH₂SSCH₂CH₃, or any combination or mixture thereof. In one embodiment, the precursor for sulfur is a reducing gas or a reducing vapor. In one embodiment, the precursor for sulfur preceding and/or following the precursor for dopant metal is a reducing gas or a reducing vapor.

In one embodiment, the precursor for selenium is selected from a group consisting of elemental selenium; H₂Se, alkaneseleniumhydride such as CH₃CH₂SeH, dialkyldiselenide compounds such as diethyldiselenide (C₂H₅SeSeC₂H₅) ; and bis (trialkylsilyl) selenium compounds such as (tBuMe₂Si)₂Se, (Et₃Si)₂Se, and (Me₃Si)₂Se). In one embodiment, the precursor for selenium is a reducing gas. In one embodiment, the precursor for selenium preceding and/or following the precursor for dopant metal is a reducing gas or a reducing vapor.

In one embodiment, the matrix material is Y₂O₃₋ₓSₓ, La₂O₃₋ₓSₓ, Gd₂O₃₋ₓSₓ, Sc₂O₃₋ₓSₓ, or Lu₂O₃₋ₓSₓ. In one embodiment, the matrix material is Y₂O₃₋ₓSeₓ, La₂O₃₋ₓSeₓ, Gd₂O₃₋ₓSeₓ, Sc₂O₃₋ₓSeₓ, or Lu₂O₃₋ₓSeₓ. In one embodiment, the matrix material is Y₂O₃₋ₓ(S,Se)ₓ, La₂O₃₋ₓ(S,Se)ₓ, Gd₂O₃₋ₓ(S,Se)ₓ, Sc₂O₃₋ₓ(S,Se)ₓ, Lu₂O₃₋ₓ(S,Se)ₓ. The pre-cursors used for forming the first deposit of matrix material may be the same ones as used for forming the second deposit of matrix material. Alternatively, at least one of the precursors used for forming the first deposit of matrix material may be different than when forming the second deposit of matrix material.

The precursor for dopant metal used for doping the surface of the first deposit of matrix material may be the same as used for doping the surface of the second deposit of matrix material. Alternatively, the precursor for dopant metal used for doping the surface of the first deposit of matrix material may be different than used for doping the surface of the second deposit of matrix material. In one embodiment, the rare-earth metal in the first layer of matrix material is the same as the rare-earth metal in the second layer of matrix material. In one embodiment, the rare-earth metal in the first layer of matrix material is different than the rare-earth metal in the second layer of matrix material.

The thickness of the material, deposit or layer produced by the ALD-type process can be increased by repeating several times a pulsing sequence comprising the aforementioned pulses containing the precursor material, and the purging periods. The number of how many times this sequence, called the “ALD cycle”, is repeated depends on the targeted thickness of the deposit or layer.

a) and b) may be carried out until the thickness of the first layer of matrix material doped with the dopant metal is 5-1000 nm or 50-500 nm. c) and d) may be carried out until the thickness of the second layer of matrix material doped with the dopant metal is 5-1000 nm or 50-500 nm.

In one embodiment, the [n_{dopant metal}]/[n_{dopant metal}+n_{matrix metal}] molar fraction of the dopant metal is 1 -20 mol-%, or 4-10 mol-%.

In one embodiment, a) of depositing the first deposit of matrix material and b) of doping the surface of the first deposit of matrix material with a dopant metal are repeated one or more times. By repeating a) and b) one or more times, one may be able to fabricate a material with a desired thickness.

In one embodiment, c) of depositing the second deposit of matrix material and d) of doping the surface of the second deposit of matrix material with a dopant metal are repeated one or more times.

In one embodiment, a) of exposing the deposition surface to a precursor for rare-earth metal, a precursor for oxygen, and one or both of a precursor for sulfur and a precursor for selenium, is repeated at least once before b).

In one embodiment, b) of exposing the deposition surface to a precursor for dopant metal is carried out once after which a) is carried out.

In one embodiment, c) of exposing the deposition surface to a precursor for rare-earth metal, a precursor for oxygen, and one or both of a precursor for sulfur and a precursor for selenium, is repeated at least once before d).

In one embodiment, d) of exposing the deposition surface to a precursor for dopant metal is carried out once after which c) is carried out.

In one embodiment, the temperature of the reaction space is 100-450 ° C., or 150-400 ° C., or 200 -350 ° C., or 250-300 ° C. In one embodiment, the formation of the first layer of matrix material doped with the dopant metal and/or of the second layer of matrix material doped with the dopant metal are/is carried out at a temperature of 100-450 ° C., or of 150-400 ° C., or of 200-350 ° C., or of 250-300 ° C.

The material is fabricated on the surface of a substrate. The material of the substrate may be selected from a group consisting of silicon (Si), glass, and ceramic.

The device comprising a material as disclosed in the present application may be a light emitting device, comprising electroluminescent displays.

The material comprising a first layer of matrix material doped with the dopant metal described in the current specification has the added utility of having the property of being able to emit blue color when being excited. The material described in the current specification has the added utility of having properties enabling its use as a phosphor material in various applications.

The method described in the current specification has the added utility of enabling to control the fabrication method such that the oxidation state of the dopant metal can be adjusted in a manner to produce a material being able to emit e.g. blue color or blue light when being excited.

### EXAMPLES

Reference will now be made in detail to the various embodiments, an example of which is illustrated in the accompanying drawing.

The description below discloses some embodiments in such a detail that a person skilled in the art is able to utilize the embodiments based on the disclosure. Not all steps or features of the embodiments are discussed in detail, as many of the steps or features will be obvious for the person skilled in the art based on this specification.

For reasons of simplicity, item numbers will be maintained in the following exemplary embodiments in the case of repeating components.

As presented above the ALD-type process is a method for depositing uniform and conformal deposits or layers over substrates of various shapes. Further, as presented above in ALD-type processes the deposit or layer is grown by alternately repeating, essentially self-limiting, surface reactions between a precursor and a surface to be coated. The prior art discloses many different apparatuses suitable for carrying out an ALD-type process. The construction of a processing tool suitable for carrying out the methods in the following embodiments will be obvious to the skilled person in light of this disclosure. The tool can be e.g. a conventional ALD tool suitable for handling the process chemicals. Many of the steps related to handling such tools, such as delivering a substrate into the reaction space, pumping the reaction space down to a low pressure, or adjusting gas flows in the tool if the process is done at atmospheric pressure, heating the substrates and the reaction space etc., will be obvious to the skilled person. Also, many other known operations or features are not described here in detail nor mentioned, in order to emphasize relewant aspects of the various embodiments of the invention.

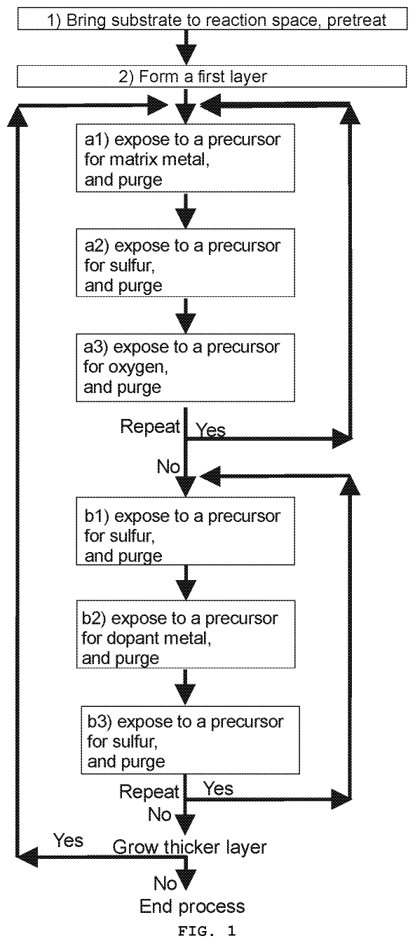

The method of FIG. 1 and the material of FIG. illustrate, respectively, a method and the corresponding material according to one embodiment. The method of FIG. 1 presents how to carry out the method for fabricating a material 1 on the surface of a substrate 2 according to one embodiment. This exemplary embodiment begins by bringing the substrate 2 into the reaction space (step 1) of a typical reactor tool, e.g. a tool suitable for carrying out an ALD-type process as a batch-type process. The reaction space is subsequently pumped down to a pressure suitable for forming a material 1, using e.g. a mechanical vacuum pump, or in the case of atmospheric pressure ALD systems and/or processes, flows are typically set to protect the deposition zone from the atmosphere. The substrate 2 is also heated to a temperature suitable for forming the material 1 by the used method. The substrate 2 can be introduced to the reaction space through e.g. an airtight load-lock system or simply through a loading hatch. The substrate 2 can be heated in situ by e.g. resistive heating elements which also heat the entire reaction space or ex situ.

After the substrate 2 and the reaction space have reached the targeted temperature and other conditions suitable for deposition, the surface of the substrate can be conditioned in step 1. This conditioning of the surface commonly includes chemical purification of the surface of the substrate 2 from impurities and/or oxidation. Also a conditioning thin film, such as a thin film of Al₂O₃ grown by ALD, may be formed on its surface to form a part of the substrate. The conditioning thin film may denote a material that covers any variation in the chemicals composition or crystallinity on the surface of the substrate, prevents possible diffusion of harmful impurity ions from the substrate to a subsequent coating, improves the adhesion of a subsequent coating on its surface and/or makes the surface more suitable for uniform ALD thin film growth. Especially removal of oxide is beneficial when the surface has been imported into the reaction space via an oxidizing environment, e.g. when transporting the exposed (silicon) surface from one deposition tool to another. The details of the process for removing impurities and/or oxide from the surface of the (silicon) substrate will be obvious to the skilled person in view of this specification. In some embodiments the conditioning can be done ex-situ, i.e. outside the tool suitable for ALD-type processes. An example of an ex-situ conditioning process is etching for 1 min in a 1% HF solution followed by rinsing in DI-water. Another example of an ex-situ conditioning process is exposing the substrate to ozone gas or oxygen plasma to remove organic impurities from the substrate surface in the form of volatile gases.

After the surface of the substrate 2 has been conditioned, an alternate exposure of the deposition surface to different chemicals is started, to form a material 1 directly on the surface of the substrate 2.

The precursors are suitably introduced into the reaction space in their gaseous form. This can be realized by first evaporating the precursors in their respective source containers which may or may not be heated depending on the properties of the precursor chemical itself. The evaporated precursor can be delivered into the reaction space by e.g. dosing it through the pipework of the reactor tool comprising flow channels for delivering the vaporized precursors into the reaction space. Controlled dosing of vapor into the reaction space can be realized by valves installed in the flow channels or other flow controllers. These valves are commonly called pulsing valves in a system suitable for ALD-type deposition.

Also other mechanisms of bringing the substrate 2 into contact with a chemical inside the reaction space may be conceived. One alternative is to make the surface of the substrate (instead of the vaporized chemical) move inside the reaction space such that the substrate moves through a region occupied by a gaseous chemical.

A reactor suitable for ALD-type deposition comprises a system for introducing carrier gas, such as nitrogen or argon into the reaction space such that the reaction space can be purged from surplus chemical and reaction by-products before introducing the next chemical into the reaction space. This feature together with the controlled dosing of vaporized precursors enables alternately exposing the surface of the substrate to precursors without significant intermixing of different precursors in the reaction space or in other parts of the reactor. In practice the flow of carrier gas is commonly continuous through the reaction space throughout the deposition process and only the various precursors are alternately introduced to the reaction space with the carrier gas. Obviously, purging of the reaction space does not necessarily result in complete elimination of surplus precursors or reaction by-products from the reaction space but residues of these or other materials may always be present.

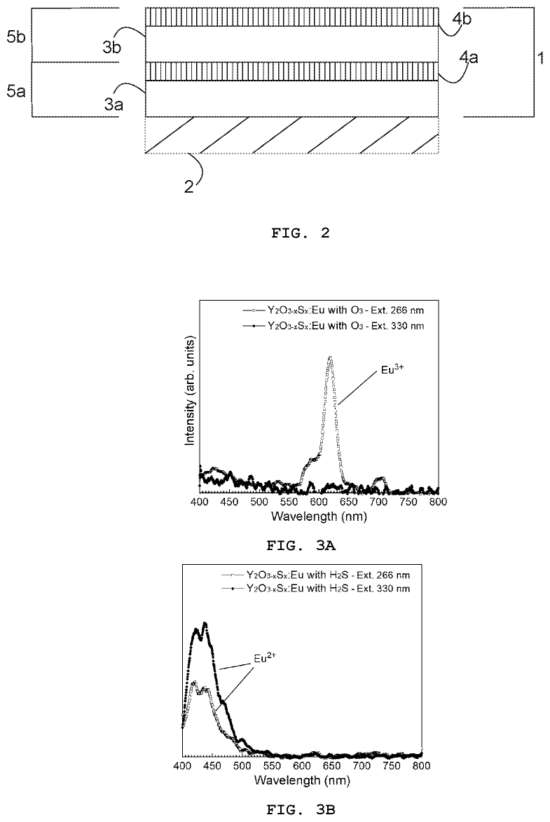

Following the step of various preparations (step 1 discussed above), in the embodiment shown in FIGS. 1, 2) of forming a first layer of matrix material doped with a dopant metal 5a is carried out; i.e. a first deposit of matrix material 3a is deposited on the deposition surface by exposing the deposition surface to alternately repeated surface reactions of a precursor for rare-earth metal, a precursor for oxygen, and a precursor for sulfur. I.e. a first deposit of matrix material 3a is formed on the surface of the substrate 2. The first deposit of matrix material 3a can be deposited by exposing, in step al), the surface of the substrate 2, i.e. the deposition surface, to a precursor for rare-earth metal, such as (CH₃Cp)₃Y. Exposure of the surface to the precursor for rare-earth metal results in the chemisorption of a portion of the introduced precursor, e.g. (CH₃Cp)₃Y, onto the surface of the substrate. After purging of the reaction space, the deposition surface may be exposed to a precursor for sulfur, e.g. H₂S, in step a2). Subsequently, the reaction space is purged again. Some of the precursor for sulfur in turn gets chemisorbed onto the surface. Thereafter, the deposition surface may be exposed to a precursor for oxygen, such as water, in step a3). Subsequently, the reaction space is purged again. Some of the precursor for oxygen in turn gets chemisorbed onto the surface.

The order of exposing the deposition surface to the above precursors may vary and the deposition surface could equally well be firstly exposed e.g. to the precursor for oxygen instead of the above mentioned order of firstly exposing the deposition surface to the precursor for rare-earth metal.

The above cycle of step a1), step a) and step a3) can be repeated e.g. 99 times. Then the process is continued by doping the surface of the first deposit with a dopant metal 4a.

The dopant metal is formed on the surface of the first deposit by exposing the surface of the first deposit to a precursor for dopant metal and a precursor for sulfur configured to provide the dopant metal in the formed first layer of matrix material doped with a dopant metal, with the oxidation state of +2. Doping the surface of the first deposit 3a can be carried out by exposing, in step b1, the deposition surface i.e. now the surface of the first deposit 3a, to a precursor for sulfur, such as H₂S, which is a reducing gas able to reduce the oxidation state of the dopant metal. Exposure of the surface to the precursor for sulfur results in the chemisorption of a portion of the introduced precursor, e.g. H₂S, onto the deposition surface. After purging of the reaction space, the deposition surface is exposed to a precursor for dopant metal, such as Eu(thd)₃. Subsequently, the reaction space is purged again. Some of the precursor for dopant metal in turn gets chemisorbed onto the surface or diffused into the surface, in the above step b2). The above step b2) can be further followed by exposure of the deposition surface to the precursor for sulfur, such as H₂S, followed by the purging step.

Each exposure of the deposition surface to a precursor, according to the embodiment of FIG. 1, results in formation of additional deposit on the deposition surface as a result of chemisorption reactions of the corresponding precursor with the deposition surface. Thickness of the material 1 on the surface of the substrate 2 can be increased by repeating step a1)-a3) and/or step b11)-b3) one or more times. The thickness of the material is increased until a targeted thickness is reached, after which the alternate exposures are stopped and the process is ended. As a result of the deposition process a material is formed on the surface of the substrate. The material also has excellent thickness uniformity and compotional uniformity along the deposition surface.

Following the above description, one may also form a second layer of matrix material doped with a dopant metal 5b based on what is described in the present specification. FIG. 2 shows one embodiment of a material 1 formed on a substrate 2 comprising a first layer of matrix material doped with a dopant metal 5a and a second layer of matrix material doped with a dopant metal 5b. The first layer of matrix material doped with a dopant metal 5a presented in FIG. 2 is formed of a first deposit of matrix material 3a that is doped with the dopant metal 4a. Similarly, the second layer of matrix material doped with a dopant metal 5b presented in FIG. 2 is formed of a second deposit of matrix material 3b that is doped with the dopant metal 4b. As clear to skilled person based on the present specification, the second layer of matrix material doped with a dopant metal may be formed of following the above description but with varying the precursors as described in the present specification.

The following example describes how a material can be fabricated on a surface orate and the test results received.

### Example 1

### Fabricating a Material on a Substrate

In this example materials comprising a first layer of matrix material doped with the dopant metal, i.e. Y₂O₃₋ₓSₓ:Eu, were formed on the surface of a substrate.

The materials were fabricated at a temperature of 300° C. on (100)-oriented Si substrates using atomic layer deposition. (CH₃Cp)₃Y, H₂O, and H₂S were used as a precursor for yttrium, precursor for oxygen, and precursor for sulfur, respectively. Eu(thd)₃ was used as the precursor for europium (Eu).

Eu was introduced into the Y₂O₃₋ₓSₓ matrix in combination either with a precursor for oxygen, O₃ (process P1, comparative example), or with a precursor for sulfur, H₂S (process P2).

After each pulse, the reaction space was purged with N₂. Depending on the pulse time, the purge time was set between 1 and 7 s. Process steps and parameters, including pulse sequences and pulse time, are presented in Table 1.

TABLE 1
Pulse sequences and corresponding pulse
time for Y₂O₂S:Eu

| Process | Pulse sequence | Pulse time (s) |
|---|---|---|
| P1 | (CH₃Cp)₃Y/H₂S/H₂O/ | 2.5/0.5/0.15/ |
| | (CH₃Cp)₃Y/H₂S/Eu(thd)₃/O₃/ | 2.5/0.5/2.5/3 |
| P2 | (CH₃Cp)₃Y/H₂S/H₂O/ | 2.5/0.5/0.15/ |
| | (CH₃Cp)₃Y/H₂S/Eu(thd)₃/H₂S | 2.5/0.5/2.5/0.5 |

FIGS. 3A and 3B show photoluminescence spectra for Y₂O₃₋ₓSₓ:Eu samples prepared using the Eu(thd)₃/O₃ (process P1, comparative example) and Eu(thd)₃/H₂S (process P2) pulse sequences, respectively. Both samples were excited with a wavelength of 266 and 330 nm. For an excitation wavelength of 330 nm, the Y₂O₃₋ₓSₓ:Eu sample prepared using O₃ shows no significant emission. However, for an excitation wavelength of 266 nm, red luminescence spectra between 550 and 720 nm, which are the typical Eu³⁺⁵D₀→⁷F_{J} (J=0, 1, 2, 3, and 4) transitions, were obtained. Unlike the sample prepared using O₃, for an excitation wavelength of 266 nm the Y₂O₃₋ₓSₓ:Eu sample prepared using H₂S exhibits a dominant broad emission band, which is typical of the 4f⁶5d¹→4f⁷ transitions in Eu²+dopants, below 500 nm. The intensity of the emission increases when the sample is excited with a wavelength of 330 nm.

FIG. 4 shows measured X-ray photoelectron spectroscopy (XPS) spectra for S 2s core levels in the materials grown using Eu(thd)₃/O₃ (process P1, comparative example) and Eu(thd)₃/H₂S (process P2) pulse sequences. No special precautions were taken to protect the samples from environmental contamination. The spectra show a significant difference between the sulfur bond in the surface layer of samples depending on the doping configuration. While sulfate bonds (Y₂(SO₄)₃) formed in the Y₂O₃₋ₓSₓ:Eu film prepared using the Eu(thd)₃/O₃ sequence, sulfide bonds are dominant in the Y₂O₃₋ₓSₓ:Eu sample grown using Eu(thd)₃/H₂S pulse sequence despite a small amount of sulfates.

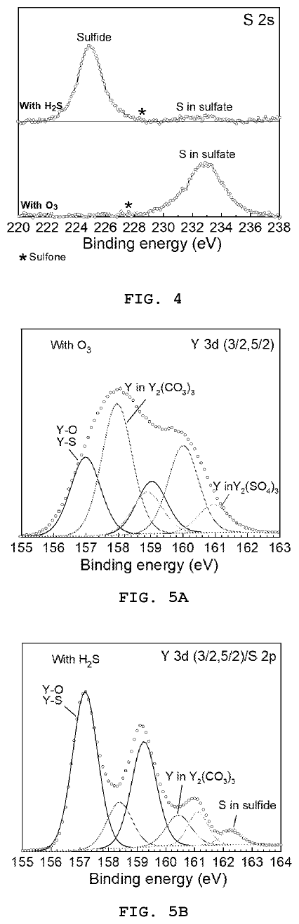

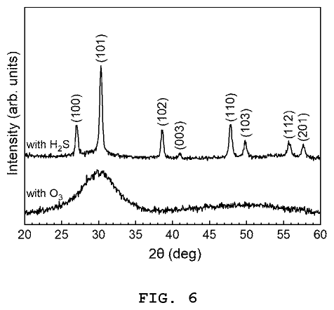

FIGS. 5A and 5B show measured and fitted XPS spectra for Y 3d and Y 3d/S 2p core levels in materials grown using Eu(thd)₃/O₃ (process P1, comparative example) and Eu(thd)₃/H₂S (process P2) pulse sequences, respectively. The spectra were fitted using voigt function. Open symbols represent measured data whereas solid lines show fitting results. The fittings were performed considering the presence of Y₂(SO₄)₃ in the sample grown using O₃. Based on fitting results, the spectra are assigned to Y in Y₂(SO₄)₃, Y in Y₂(CO₃)₃, Y—O/Y—S bonds as well as S in sulfide compounds. While the Y₂(CO₃)₃ and Y—O/Y—S bonds are present in both films, sulfides are mainly found in the Y₂O₃₋ₓSₓ:Eu sample grown using the Eu(thd)₃/H₂S sequence. This is consistent with S 2s core level spectra shown in FIG. 4.

The elemental composition of the films was estimated from XPS measurements using C 1s, Eu 3d, O 1s, S 2s and Y 3p core levels. The results are summarized in Table 2. Carbon contamination was measured in both samples and, as expected the film grown using the Eu(thd)₃/O₃ (process P1, comparative example) pulse sequence has higher oxygen content in comparison to the one grown using the Eu(thd)₃/H₂S (process P2) sequence with an O/S ratio of 8.1 and 5.7, respectively.

TABLE 2
Comparison of the elemental composition of the surface
layer in Eu-doped Y₂O₃₋ₓSₓ films prepared using Eu(thd)₃/
O₃ (process P1, comparative example) and Eu(thd)₃/H₂S
(process P2) pulse sequences.

| | Y | O | S | C | Eu |
|---|---|---|---|---|---|
| Process | (at. %) | (at. %) | (at. %) | (at. %) | (at. %) |
| P1 | 10.6 | 48.7 | 6.0 | 30.8 | 3.9 |
| P2 | 14.7 | 39.7 | 6.9 | 31.0 | 7.7 |

FIG. 6 shows X-ray diffraction (XRD) patterns measured between 20 and 60° at a fixed grazing incidence angle of 1° on Y₂O₃₋ₓSₓ:Eu samples prepared using the Eu(thd)₃/O₃ (process P1, comparative example) and Eu(thd)₃/H₂S (process P2) pulse sequences. The sample grown using O₃ shows a single very broad peak around 30° suggesting that the layer has a rather amorphous structure. However, the one grown using H₂S shows several sharp peaks indicating that the film has a crystalline structure. (100), (101), (102), (003), (110), (103), (112) and (201) reflections were identified meaning that the films grown using the Eu(thd)₃/H₂S pulse sequence have a hexagonal crystal structure.

### Example 2

### Fabricating a Material on a Substrate

In the below table is presented materials prepared following the description in example 1 but by varying the precursors used. Either process P1 or process P2 was followed. Cp denotes cyclopentadienyl, ⁱPr denotes isopropyl, thd denotes 2,2,6,6-tetramethyl-3, 5-heptanedionate, and TDIPAALu denotes tris(N,N′-di-i-propylacetamidinato)lutetium.

| Process | Material | Pulse sequence |
|---|---|---|
| P1 | Y₂O₃₋ₓSₓ:Eu³⁺ | (CH₃Cp)₃Y/H₂S/H₂O/(CH₃Cp)₃Y/ |
| | | H₂S/Eu(thd)₃/O₃ |
| P2 | Y₂O₃₋ₓSₓ:Eu²⁺ | (CH₃Cp)₃Y/H₂S/H₂O/(CH₃Cp)₃Y/ |
| | | H₂S/Eu(thd)₃/H₂S |
| P1 | Sc₂O₃₋ₓSₓ:Eu³⁺ | (Cp)₃Sc/H₂S/H₂O/Cp₃Sc/H₂S/Eu(thd)₃/O₃ |
| P2 | Sc₂O₃₋ₓSₓ:Eu²⁺ | (Cp)₃Sc/H₂S/H₂O/Cp₃Sc/H₂S/Eu(thd)₃/H₂S |
| P1 | La₂O₃₋ₓSₓ:Eu³⁺ | (ⁱPrCp)₃La/H₂S/H₂O/(ⁱPrCp)₃La/ |
| | | H₂S/Eu(thd)₃/O₃ |
| P2 | La₂O₃₋ₓSₓ:Eu²⁺ | (ⁱPrCp)₃La/H₂S/H₂O/(ⁱPrCp)₃ |
| | | La/H₂S/Eu(thd)₃/H₂S |
| P1 | Gd₂O₃₋ₓSₓ:Eu³⁺ | (CH₃Cp)₃ Gd/H₂S/H₂O/(CH₃Cp)₃ |
| | | Gd/H₂S/Eu(thd)₃/O₃ |
| P2 | Gd₂O₃₋ₓSₓ:Eu²⁺ | (CH₃Cp)₃Gd/H₂S/H₂O/ |
| | | (CH₃Cp)₃Gd/H₂S/Eu(thd)₃/H₂S |
| P1 | Lu₂O₃₋ₓSₓ:Eu³⁺ | TDIPAALu/H₂S/H₂O/TDIPAALu/ |
| | | H₂S/Eu(thd)₃/O₃ |
| P2 | Lu₂O₃₋ₓSₓ:Eu²⁺ | TDIPAALu/H₂S/H₂O/TDIPAALu/ |
| | | H₂S/Eu(thd)₃/H₂S |
| P1 | Y₂O₃₋ₓSeₓ:Eu³⁺ | (CH₃Cp)₃Y/C₂H₅SeSeC₂H₅/H₂O/ |
| | | (CH₃Cp)₃Y/C₂H₅SeSeC₂H₅/Eu(thd)₃/O₃ |
| P2 | Y₂O₃₋ₓSeₓ:Eu²⁺ | (CH₃Cp)₃Y/C₂H₅SeSeC₂H₅/H₂O/ |
| | | (CH₃Cp)₃Y/C₂H₅SeSeC₂H₅/ |
| | | Eu(thd)₃/C₂H₅SeSeC₂H₅ |

It is obvious to a person skilled in the art that with the advancement of technology, the basic idea may be implemented in various ways. The embodiments are thus not limited to the examples described above; instead they may vary within the scope of the claims.

The embodiments described hereinbefore may be used in any combination with each other. Several of the embodiments may be combined together to form a further embodiment. A material, a method, or a device, disclosed herein, may comprise at least one of the embodiments described hereinbefore. It will be understood that the benefits and advantages described above may relate to one embodiment or may relate to several embodiments. The embodiments are not limited to those that solve any or all of the stated problems or those that have any or all of the stated benefits and advantages. It will further be understood that reference to ‘an’ item refers to one or more of those items. The term “comprising” is used in this specification to mean including the feature(s) or act(s) followed thereafter, without excluding the presence of one or more additional features or acts.

1. A material comprising a first layer of matrix material doped with a dopant metal, wherein the matrix material comprises a rare-earth metal, oxygen, and one or both of sulfur and selenium, and wherein, in the first layer of matrix material doped with the dopant metal, the rare-earth metal has an oxidation state of +3 and the dopant metal has an oxidation state of +2.

2. The material of claim 1, wherein the material is a phosphor material.

3. The material of claim 1, wherein the first layer of matrix material doped with the dopant metal emits electromagnetic radiation with a wavelength of 400-500 nm or 450-485 nm when excited.

4. The material of claim 1, wherein the material further comprises a second layer of matrix material doped with a dopant metal, wherein the matrix material comprises a rare-earth metal, oxygen, and one or both of sulfur and selenium, and wherein, in the second layer of matrix material doped with the dopant metal, the rare-earth metal has an oxidation state of +3 and the dopant metal has an oxidation state of +3.

5. The material of claim 1, wherein the rare-earth metal is yttrium, scandium, lanthanum, gadolinium, or lutetium.

6. The material of claim 1, wherein the dopant metal is europium.

7. A method for fabricating a material on a surface of a substrate, wherein the method comprises forming a first layer of matrix material doped with a dopant metal, wherein the matrix material comprises a rare-earth metal, oxygen, and one or both of sulfur and selenium, and
wherein the first layer of matrix material doped with the dopant metal is formed in a reaction space through alternately repeated surface reactions of precursors by
a) depositing a first deposit of matrix material by exposing a deposition surface to a precursor for rare-earth metal, a precursor for oxygen, and one or both of a precursor for sulfur and a precursor for selenium in any order, and
b) doping the surface of the first deposit of matrix material with the dopant metal by exposing the deposition surface to a precursor for dopant metal,
wherein exposing the deposition surface to the precursor for dopant metal is preceded with exposing the deposition surface to either a precursor for sulfur or a precursor for selenium configured to provide the dopant metal, in the first layer of matrix material doped with the dopant metal, with an oxidation state of +2, while the rare-earth metal has an oxidation state of +3.

8. The method of claim 7, wherein exposing the deposition surface to the precursor for dopant metal in b) is followed by exposing the deposition surface to either a precursor for sulfur or a precursor for selenium.

9. The method of claim 7, wherein the precursor for rare-earth metal is selected from a group consisting of a precursor for yttrium, precursor for scandium, precursor for lanthanum, precursor for gadolinium, and precursor for lutetium.

10. The method of claim 7, wherein the precursor for dopant metal is a precursor for europium.

11. The method of claim 7, wherein the method further comprises forming a second layer of matrix material doped with a dopant metal, wherein the matrix material comprises a rare-earth metal, oxygen, and one or both of sulfur and selenium, and
wherein the second layer of matrix material doped with the dopant metal is formed in a reaction space through alternately repeated surface reactions of precursors by
c) depositing a second deposit of matrix material by exposing a deposition surface to a precursor for rare-earth metal, a precursor for oxygen, and one or both of a precursor for sulfur and a precursor for selenium in any order, and
d) doping the surface of the second deposit of matrix material with a dopant metal by exposing the deposition surface to a precursor for dopant metal,
wherein exposing the deposition surface to the precursor for dopant metal in d) is followed by exposing the deposition surface to a precursor for oxygen, such that, in the second layer of matrix material doped with the dopant metal , the rare-earth metal has an oxidation state of +3 and the dopant metal has an oxidation state of +3.

12. A light emitting device comprising the material of claim 1.
